(19) United States
(12) Patent Application Publication
(10) Pub. No.: US 2008/0099681 A1
(43) Pub. Date: May 1, 2008

(54) Infrared Detector and Process for Fabricating the Same

(76) Inventors: Yasuhiro Shimada, Kyoto (JP); Daisuke Ueda, Osaka (JP)

Correspondence Address: MCDERMOTT WILL & EMERY LLP, 600 13TH STREET, NW, WASHINGTON, DC, 20005-3096, US

(21) Appl. No.: 10/589,724

(22) PCT Filed: Feb. 17, 2004
(86) PCT No.: PCT/JP04/01706

§ 371 Date: Aug. 17, 2006

(51) Int. Cl. G01J 5/00; H01L 21/00

(52) U.S. Cl. 250/338.3; 438/54; 257/E21.001

(57) ABSTRACT

First, an electrode is formed on an insulation layer that has been formed on a silicon substrate, when manufacturing an infrared detection device. The electrode has a shape matching that of a thermal resistance element constituting the infrared detection device. A semiconductor substrate is placed in a reaction chamber, given a predetermined potential, and heated. Next, a material of a thermal resistor substance constituting the thermal resistance element is vaporized into a gaseous material, and the gaseous material is ion-clusterized and supplied into the reaction chamber. The gaseous material collects toward the electrode as a result of an action of an electric field generated by giving the electrode the predetermined potential. The gaseous material that came into contact with the electrode is stabilized by receiving electrons, and thermally decomposes, thus growing a thermal resistor substance on the electrode.

### TECHNICAL FIELD

The present invention relates to an infrared detection device and a manufacturing method for the same, and in particular to technology for improving a thermal sensitivity of the infrared detection device.

### BACKGROUND ART

In recent years, there has been a steadily growing demand for resistance bolometer infrared imaging devices, which are small and inexpensive infrared imaging devices. Resistance bolometer infrared imaging devices use, as an imaging element, a thermal resistor substance whose electrical resistance varies according to temperature.

FIG. 7 shows an exemplary circuit configuration of an infrared detector constituting a pixel of a resistance bolometer infrared imaging device. As shown in FIG. 7, an infrared detector 6 includes a transistor 62 and a thermal resistance element 63. An electrode at one end of the thermal resistance element 63 is connected to a source electrode of the transistor 62, and an electrode at the other end of the thermal resistance element 63 is connected to a cell plate line 64. Also, a drain electrode of the transistor 62 is connected to a bit line 60, and a gate electrode is connected to a word line 61.

FIG. 8 is a cross-sectional view showing an exemplary element structure of the infrared detector 6. As shown in FIG. 8, the infrared detector 6 has a stack structure. The thermal resistance element 63 has a three-layer structure in which a thermal resistor substance 71 is sandwiched between electrodes 70 and 72. The electrode 72 is connected to a source electrode 74 of the transistor 62 via a contact plug 73, and the electrode 70 is connected to the cell plate line 64. A drain electrode 75 of the transistor 62 is connected to the bit line 60 via a contact plug 77, and a gate electrode 76 is connected to a word line 61 (not depicted).

A method of forming the thermal resistance element 63 with this kind of structure is disclosed in, for example, Japanese Patent Application Publication No. 2002-284529 which teaches the following method. FIGS. 9A and 9B are cross-sectional views showing a method of forming the thermal resistance element 63. As shown in FIG. 9A, the electrode 72, the thermal resistor substance 71 and the electrode 70 are laminated on a support substrate 8, which is composed of an insulation layer 81 formed on a silicon substrate 82. A resist mask 80 is then formed on the top layer. Next, using the resist mask 80 as an etch mask, the configuration of FIG. 9B is achieved by, for example, a plasma etching method.

### DISCLOSURE OF THE INVENTION

If a plasma etching method is used, however, damage due to large amounts of active species such as reactive radicals occurs at of course etched surfaces of the thermal resistor substance, and this damage spreads to inner portions of the thermal resistor substance, thereby forming damaged regions 83. These damaged regions 83 do not function as a thermal resistor substance, and reduce the effective area of the thermal resistance element 63. Specifically, the damaged regions 83 extend from the outer walls of the thermal resistance element 63 inward for tens of nanometers to hundreds of nanometers, and effects from the reduction of the effective area of the thermal resistance element 63 cannot be ignored if the area of the thermal resistance element falls below 1 μm².

There is, for example, a method of performing recovery anneal processing after formation of the thermal resistance element 63 in order to reduce these damaged regions 83. The damaged regions 83 cannot, however, be completely eliminated by this recovery anneal processing.

Also, given that a temperature substantially equal to the crystallization temperature of the thermal resistor substance is applied in the recovery anneal process, the recovery anneal processing must be performed on each layer if the thermal resistance element is multilayered, which causes thermal degradation in wiring between the layers.

Also, polycrystallization of the thermal resistor substance 71 cannot be avoided in conventional technology since the thermal resistor substance 71 is formed on an upper anterior surface of the single-layer electrode 72 using a sputter method, a sol-gel method, or the like. When the thermal resistor substance 71 polycrystallizes, it becomes difficult to distinguish resistance variations attributable -to variations in the temperature of the thermal resistor substance, because resistance also occurs at crystal grain boundaries.

As a result of the above reasons, it is difficult to conventionally obtain a thermal resistor substance with good thermal sensitivity.

The present invention has been achieved in view of the above issue, and aims to provide a resistance bolometer infrared detection device and a manufacturing method for the same that improve the thermal sensitivity of a thermal resistance element.

In order to achieve the above aim, a manufacturing method for an infrared detection device pertaining to the present invention is a manufacturing method for an infrared detection device including a thermal resistance element in which a thermal resistor substance contacts an electrode, the manufacturing method including an electrode formation step of forming the electrode in a predetermined shape on a substrate; and a growth step of growing the thermal resistor substance on the electrode.

According to this method, the thermal resistor substance is selectively grown on only a preconfigured electrode, thereby eliminating the need to perform configuration again by etching after growing the thermal resistor substance. It is therefore possible to improve the thermal sensitivity of the thermal resistance element since damaged regions of the thermal resistor substance are substantially eliminated.

Also, a manufacturing method for an infrared detection element pertaining to the present invention is a manufacturing method for an infrared detection device including a thermal resistance element in which a thermal resistor substance whose resistance changes according to temperature contacts an electrode, the manufacturing method including an electrode formation step of forming the electrode on a semiconductor substrate; a thin film formation step of forming a thin film on the electrode; a thin film removal step of removing a portion of the thin film to expose the electrode; and a growth step of growing the thermal resistor substance on the exposed electrode.

According to this method, the thermal resistor substance is selectively grown only at a predetermined position on an electrode, thereby eliminating the need to perform configuration again by etching after growing the thermal resistor substance. It is therefore possible to improve the thermal sensitivity of the thermal resistance element since damaged regions of the thermal resistor substance are substantially eliminated.

Also, in the manufacturing method for the infrared detection device pertaining to the present invention, the growth step may selectively grow the thermal resistor substance on only the electrode by a vapor growth method. For example, the vapor growth method may be a metal-organic chemical vapor deposition method. According to this method, it is possible to improve a self-selectivity of the thermal resistor substance in the formation process thereof.

Also, the growth step may include a vaporization step of vaporizing a composition material of the thermal resistor substance into a gaseous material; an ion clusterization step of ion clusterizing the gaseous material; a collection step of collecting the ion clusterized gaseous material on the electrode by giving the electrode a predetermined electric potential to generate an electric field; and a condensation step of causing the ion clusterized gaseous material to condense on the electrode by heating the electrode to a predetermined temperature, to grow the thermal resistor substance. According to this method, the thermal resistor substance can be grown selectively.

Also, in the manufacturing method for the infrared detection device pertaining to the present invention, the growth step may selectively grow the thermal resistor substance by a liquid-phase growth method. For example, the liquid-phase growth method may be an electrophoresis method. According to this method, it is possible to improve the self-selectivity of the thermal resistor substance in the formation process thereof.

Also, the growth step may include a colloidization step of colloidizing a composition material of the thermal resistor substance into colloid particles; a suspension generation step of generating a suspension including the colloid particles; an electric field generation step of, with the semiconductor substrate being immersed in the suspension, applying a predetermined voltage to the electrode to generate an electric field; and an aggregation step of causing the colloid particles to aggregate on the electrode by an action of the electric field, to grow the thermal resistor substance. The thermal resistor substance can be selectively grown according to this method as well.

Also, according the above method, it is possible for the thermal resistor substance to self-aligningly formed on an electrode with an arbitrary shape. It is therefore possible to eliminate formation/manufacturing processes of the thermal resistor substance material, and cut the cost of manufacturing the infrared detection device.

Also, in the manufacturing method for the infrared detection device pertaining to the present invention, a crystal lattice constant of the electrode, along an interface with the thermal resistor substance, may be substantially equal to a crystal lattice constant of the thermal resistor substance. According to this method, it is possible to have a single-crystal thermal resistor substance, thereby enabling an improvement in the sensitivity of the infrared detection device.

Also, in the manufacturing method for the infrared detection device pertaining to the present invention, a material of the thermal resistor substance may be a strongly correlated electron material expressed by a general formula PrₓCa₁₋ₓMnO₃, to which a metal oxide, having a perovskite structure that includes an alkaline-earth metal or a rare-earth metal, has been added. According to this method, it is possible to improve the sensitivity of the thermal resistor substance, and expand the temperature range in which the thermal resistor substance can effectively detect infrared light. Furthermore, the temperature range in which the infrared detection device can be used is also expanded.

Also, in the manufacturing method for the infrared detection device pertaining to the present invention, the thin film may be an insulation film. According to this method, the thin film can be used, as is, as an interlayer insulation film.

Also, in the manufacturing method for the infrared detection device pertaining to the present invention, the thermal resistor substance may be a single crystal. According to this method, resistance due to crystal grain boundaries does not occur since there are no crystal grain boundaries in the thermal resistor substance. The sensitivity of the infrared detection device can therefore be improved since it is possible to increase the resistance change resulting from a change in temperature, in comparison to the resistance of the entire thermal resistor substance. It is also possible to set the crystal orientation of the thermal resistor substance to an orientation that maximizes the sensitivity of the infrared detection device.

Also, in order to achieve the above aim, an infrared detection device pertaining to the present invention is an infrared detection device including a thermal resistance element in which a thermal resistor substance whose resistance changes according to temperature contacts an electrode, the infrared detection device being manufactured by a manufacturing method including an electrode formation step of forming an electrode in a predetermined shape on a substrate; and a growth step of growing a thermal resistor substance on the electrode. According to this structure, damaged regions of the thermal resistor substance can be substantially eliminated since there is no need to perform configuration by etching or the like after growing the thermal resistor substance. It is therefore possible to improve the thermal sensitivity of the thermal resistance element.

Also, an infrared detection device pertaining to the present invention is an infrared detection device including a thermal resistance element in which a thermal resistor substance whose resistance changes according to temperature contacts an electrode, the infrared detection device being manufactured by a manufacturing method including an electrode formation step of forming the electrode on a semiconductor substrate; a thin film formation step of forming a thin film on the electrode; a thin film removal step of removing a portion of the thin film to expose the electrode; and a growth step of growing the thermal resistor substance on the exposed electrode. According to this structure as well, it is possible to improve the thermal sensitivity of the thermal resistance element since there is no need to perform configuration by etching or the like after growing the thermal resistor substance, and damaged regions of the thermal resistor substance can be substantially eliminated.

For example, when growing the thermal resistor substance, the growth step may selectively grow the thermal resistor substance on only the electrode by a vapor growth method. Specifically, it is preferable for the vapor growth method to be a metal-organic chemical vapor deposition method. Also, the growth step may include a vaporization step of vaporizing a composition material of the thermal resistor substance into a gaseous material; an ion clusterization step of ion clusterizing the gaseous material; a collection step of collecting the ion clusterized gaseous material on the electrode by giving the electrode a predetermined electric potential to generate an electric field; and a condensation step of causing the ion clusterized gaseous material to condense on the electrode by heating the electrode to a predetermined temperature, to grow the thermal resistor substance.

Also, the growth step may selectively grow the thermal resistor substance by a liquid-phase growth method. Specifically, it is preferable for the liquid-phase growth method to be an electrophoresis method. Also, the growth step may include a colloidization step of colloidizing a composition material of the thermal resistor substance into colloid particles; a suspension generation step of generating a suspension including the colloid particles; an electric field generation step of, with the semiconductor substrate being immersed in the suspension, applying a predetermined voltage to the electrode to generate an electric field; and an aggregation step of causing the colloid particles to aggregate on the electrode by an action of the electric field, to grow the thermal resistor substance.

Also, in the infrared detection device pertaining to the present invention, a crystal lattice constant of the electrode, along an interface with the thermal resistor substance, may be substantially equal to a crystal lattice constant of the thermal resistor substance. According to this structure, it is possible to have a single-crystalline thermal resistor substance, thereby enabling an improvement in the sensitivity of the infrared detection device.

Also, in the infrared detection device pertaining to the present invention, a material of the thermal resistor substance may be a strongly correlated electron material expressed by a general formula PrₓCa₁₋ₓMnO₃, to which a metal oxide, having a perovskite structure that includes an alkaline-earth metal or a rare-earth metal, has been added. According to this structure, it is possible to improve the sensitivity of the thermal resistor substance, and expand the temperature range in which the thermal resistor substance can effectively detect infrared light. Furthermore, the temperature range in which the infrared detection device can be used is also expanded.

Also, in the infrared detection device pertaining to the present invention, the thin film may be an insulation film. According to this structure, the thin-film can be used, as is, as an interlayer insulation film.

Also, in the infrared detection device pertaining to the present invention, the thermal resistor substance may be a single crystal. According to this structure, crystal grain boundaries do not occur in the thermal resistor substance, and thus there is no resistance as a result of crystal grain boundaries. The sensitivity of the infrared detection device can therefore be improved since it is possible to increase the resistance change resulting from a change in temperature, in comparison to the resistance of the entire thermal resistor substance. It is also possible to set the crystal orientation of the thermal resistor substance to an orientation that maximizes the sensitivity of the infrared detection device.

Also, according to the present invention, the infrared detection device can be reduced in size by increasing the pixel density thereof.

### BRIEF DESCRIPTION OF THE DRAWINGS

FIG. 1 is a cross-sectional view showing an element structure of an infrared imaging element according to embodiment 1 of the present invention;

FIGS. 2A and 2B show a manufacturing method of a thermal resistance element 10 according to embodiment 1 of the present invention;

FIGS. 3A to 3C show a manufacturing method (first part) of the thermal resistance element 10 according to embodiment 2 of the present invention;

FIGS. 4A and 4B show a method of using an ion cluster method to grow a thermal resistor substance according to embodiment 2 of the present invention;

FIGS. 5A to 5C show the manufacturing method (latter part) of the thermal resistance element 10 according to embodiment 2 of the present invention;

FIG. 6 shows a method of using an electrophoresis method to grow the thermal resistor substance according to embodiment 3 of the present invention;

FIG. 7 shows an exemplary circuit structure of an infrared detector constituting a single pixel of a resistance bolometer infrared imaging device according to conventional technology;

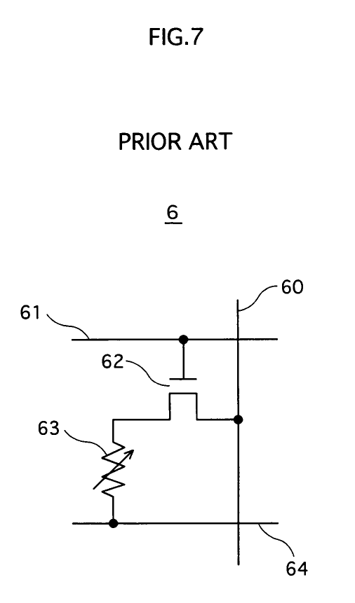

FIG. 8 is a cross-sectional view showing an exemplary element structure of an infrared detector 6; and

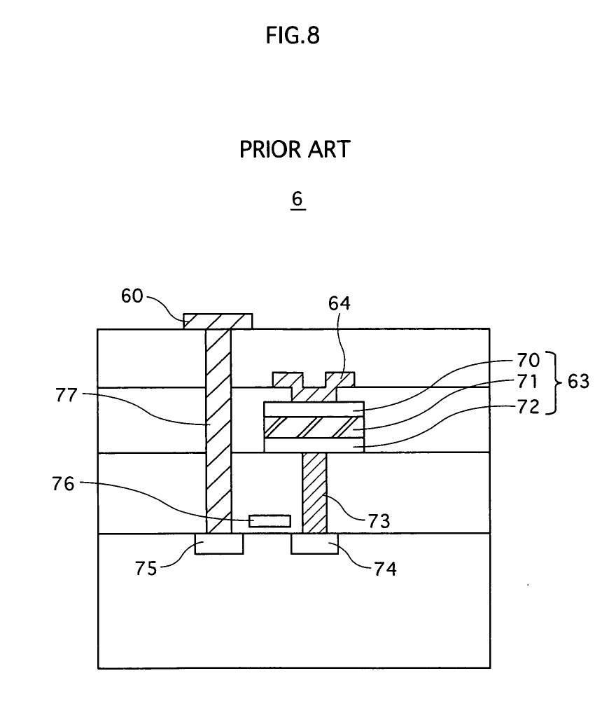

FIGS. 9A and 9B are cross sectional views showing a method of growing a thermal resistance element 63.

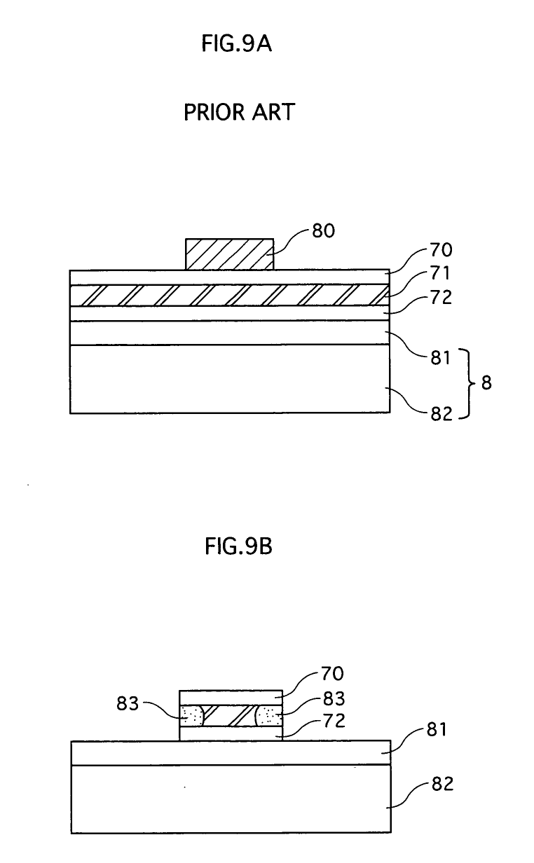

### BEST MODE FOR CARRYING OUT THE INVENTION

Embodiments of an infrared detection device and a manufacturing method for the same pertaining to the present invention are described below with reference to the drawings, taking the example of an infrared imager and with particular attention on an infrared detection device constituting the infrared imager.

### (1) Embodiment 1

An infrared imager pertaining to the present embodiment includes an infrared imaging element in which thermal resistance elements are arranged in a one-dimensional or two-dimensional array on a silicon substrate.

### (1-1) Device Structure

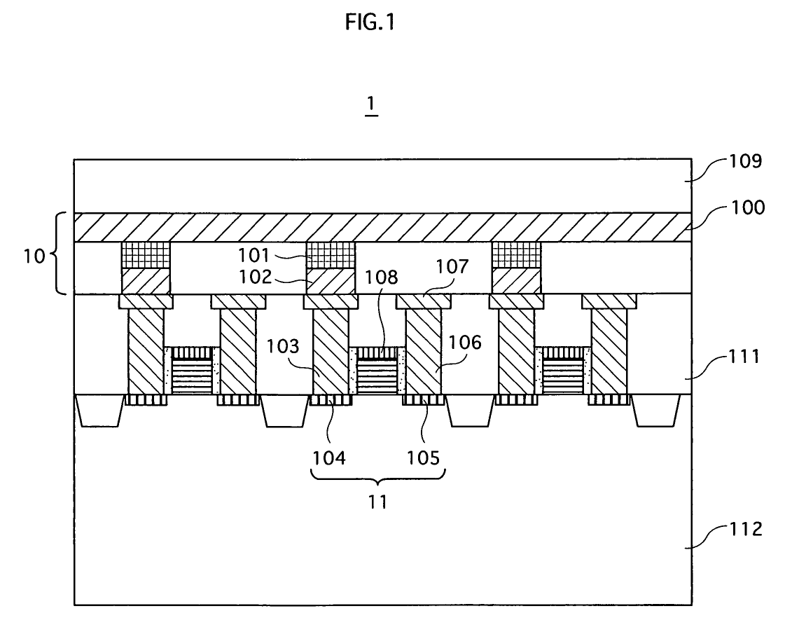

FIG. 1 is a cross-sectional view showing a portion of an element structure of the infrared imaging element pertaining to the present embodiment. As shown in FIG. 1, an infrared imaging element 1 is a semiconductor element in which an insulation layer 111 is formed on a silicon substrate 112, and groups of thermal resistance elements 10 and transistors 11 are arranged in an array, whereby each group is a pixel.

The thermal resistance elements 10 have a structure in which thermal resistor substances 101 are formed self-aligningly between a cell plate line 100 and electrodes 102. Also, the transistors 11 include a source electrode 104, a drain electrode 105 and a gate electrode 108. The electrodes 102 of the thermal resistance elements 10 and the source electrodes 104 are connected via contact plugs 103. The drain electrodes 105 are connected to bit lines 107 via contact plugs 106. Also, the gate electrodes 108 are connected to a word line which is not depicted.

The thermal resistance elements 10 are covered by an insulation layer 110. Furthermore, the cell plate line 100 is covered by an insulation layer 109.

The thermal resistor substances 101 may be, for example, a metal oxide material expressed by the general formula A₁₋ₓBₓMn_{z}O_{w} or the general formula A₁₋ₓ(B_{1-y}C_{y})ₓMn_{z}O_{w}. Here, A is a rare-earth metal such as lanthanum (La), neodymium (Nd), cerium (Ce), praseodymium (Pr) etc., or a group V element such as vanadium (V) or the like. B and C are alkaline-earth metals such as calcium (Ca), strontium (Sr), barium (Ba), etc. Also, x, y, z and w express chemical relative proportions, and can take a value of 0.

Also, a metal oxide having a perovskite structure and including an alkaline-earth metal or rare-earth metal may be used, and titanium oxide or nickel oxide may be used as the thermal resistor substance material.

Also, the thermal resistor substance may be a material composed of a strongly correlated electron material, expressed by the general formula PrₓCa₁₋ₓMnO₃, to which a metal oxide having a perovskite structure and including an alkaline-earth metal or rare-earth metal has been added. In this case, it is preferable to use manganese oxide, titanium oxide, aluminum oxide, gallium oxide, or cobalt oxide as the metal oxide. Using this kind of strongly correlated electron material enables an improvement in the sensitivity of the thermal resistor substances, as well as enables an expansion of the temperature range in which the thermal resistor substances can effectively detect infrared light. It is also possible to expand the temperature range in which the infrared detection device can be used.

### (1-2) Manufacturing Method

Next is a description of a manufacturing method for the infrared imager pertaining to the present embodiment, and in particular, of the thermal resistance element 10. Selectively growing thermal resistor substances as single crystals on electrodes is a feature of the manufacturing method of the thermal resistance element pertaining to the present invention. As an example of the manufacturing method of the present embodiment, the following describes a manufacturing method using ion clusterization.

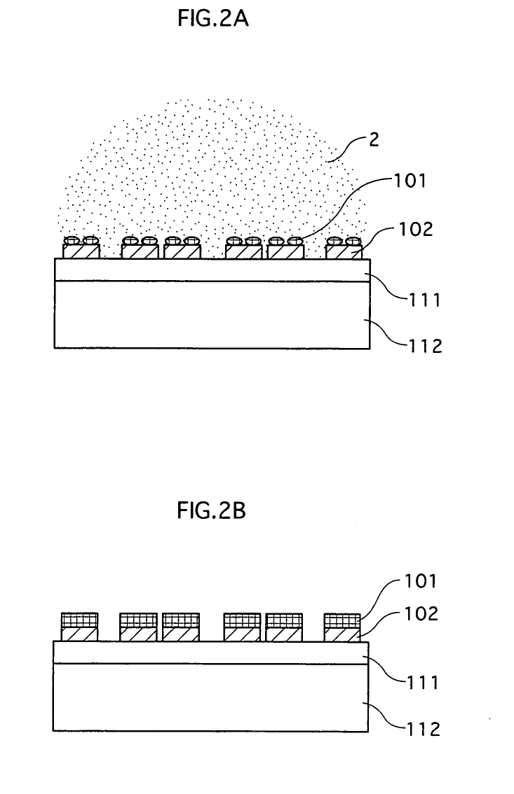

FIGS. 2A and 2B show the manufacturing method of the thermal resistance elements 10. Electrodes 102 are first formed on the insulation layer 111 which has been formed on the silicon substrate 112, when forming the thermal resistance elements 10 as shown in FIG. 2A. Note that the transistors 11 have already been formed at this point, but are not depicted in the figure.

In this state, the silicon substrate 112 is placed and held on a heating apparatus in a reaction chamber (not depicted), and a gaseous material 2 is supplied after electrically grounding the silicon substrate 112.

This gaseous material 2 is a gaseous material used in MOCVD (Metal Organic Chemical Vapor Deposition). The gaseous material 2 is composed of organic metal particles that have been vaporized, then passed through a corona discharge path to be ionized and organized into positively charged ion clusters. Note that an ionization apparatus other than a corona discharge path may be used when generating the gaseous material 2.

Due to the fact that a gas which has been ion clusterized in this way is energetically unstable, the gas tends to receive electrons in order to stabilize. In the present embodiment as well, the gaseous material 2 receives electrons from the ground potential electrodes 102 in order to stabilize, the gaseous material 2 is thermally decomposed, and the thermal resistor substances 101 are grown selectively on the electrodes 102. More specifically, the ion clusterized gaseous material 2 self-organizes on the electrodes 102. In other words, particles of the same type self-aligningly aggregate due to chemical affinity between clusters.

In this case, single crystal thermal resistor substances 101 are grown epitaxially on the electrodes 102 if a crystal lattice constant in the surface direction of the electrodes 102 is substantially matched to a crystal lattice constant of the thermal resistor substances 101. It is preferable to grow the single-crystal thermal resistor substances 101 such that their crystal orientation (which causes the thermal resistor substances 101 to be highly sensitive) is aligned in a direction perpendicular to the surface of the electrodes 102.

Note that the gaseous material 2 neither condenses nor thermally decomposes on portions of the insulation substrate 111 which are not covered by the electrodes 102. The single crystal thermal resistor substances 101 therefore grow only on the electrodes 102, as shown in FIG. 2B.

After this, the insulation layer 110 is formed so as to completely bury the thermal resistor substances 101, and then chemically-mechanically polished until upper potions of the thermal resistor substances 101 are exposed. The cell plate line 100, which also acts as electrodes for the thermal resistance elements 10, is laminated, and the insulation layer 109 is further formed, thereby completing the infrared imaging element 1.

Given that the thermal resistor substances 101 of the resulting thermal resistance elements 10 are a single crystal, and an electric field is applied to the crystal orientation of the thermal resistor substances 101 in a direction that develops large sensitivity, sensitivity and response are improved significantly compared to conventional multicrystalline thermal resistance elements.

Unlike conventional technology, there is no need to use a plasma etching method since the thermal resistor substances are formed selectively on the electrodes 102. It is therefore possible to develop large sensitivity since damaged regions are not generated, and the effective area can be expanded. As mentioned above, temperature characteristics of each pixel can be significantly improved according to the present embodiment.

### (1-3) Variations

Although the case in which the thermal resistor substances 101 are selectively grown mainly in a gas phase is described above, the present invention is of course not limited to this. The following may be implemented instead. Specifically, colloid particles of the thermal resistor substance may be suspended in a colloid solution, and microparticles of the thermal resistor substance may be electrophoresed and deposited on desired electrodes.

### (2) Embodiment 2

Although an infrared imaging device pertaining to the present embodiment has a structure that is generally the same as the infrared imaging device pertaining to the above embodiment 1, a manufacturing method of thermal resistance elements in the present embodiment differs from that of embodiment 1.

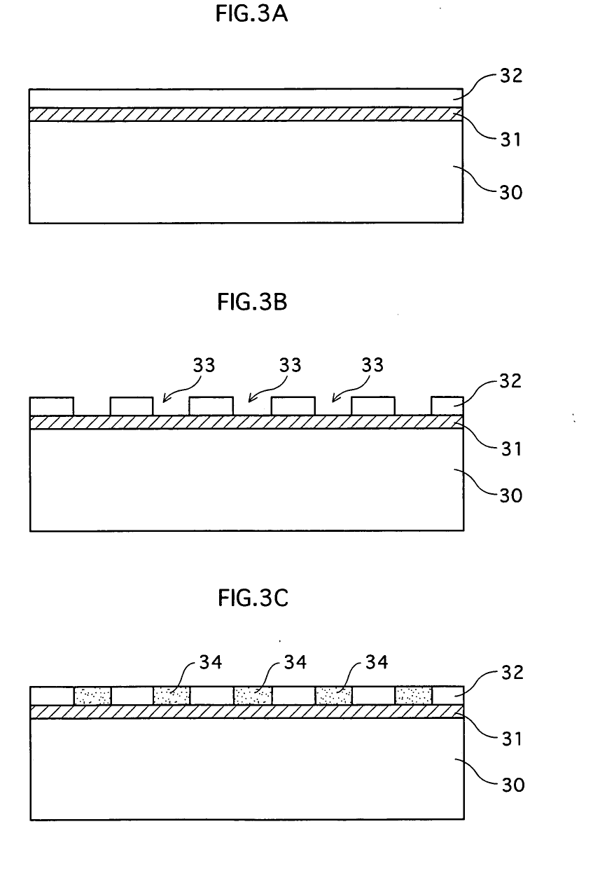

FIGS. 3A to 3C are cross-sectional views showing a manufacturing method of thermal resistance elements of the infrared imaging device pertaining to the present embodiment.

As shown in FIG. 3A, a conductive film 31 is first formed on a silicon substrate 30, and a thin film 32 is further formed thereupon. The thin film 32 is, for example, a silicon dioxide film.

Next, as shown in FIG. 3B, apertures 33 are formed in the thin film 32 to expose portions of a surface of the conductive film 31 below the thin film 32.

A shape of the apertures 33 is conformed to an external shape of the thermal resistor substances to be formed. Also, it is desirable to make aperture dimensions of the apertures 33 larger than the minimum processing dimensions that can be utilized in the present device manufacturing process.

The thin film 32 may be etched by a lithography method using a resist mask as a transfer pattern when forming the apertures 33. Alternatively, the thin film 32 may be irradiated with an energy beam such as an electron beam or ultraviolet rays at aperture 33 sites, whereby the aperture 33 sites of the thin film 32 are caused to deteriorate and be removed.

Next, as shown in FIG. 3C, thermal resistor substances 34 are selectively formed so as to fill in the apertures 33. As mentioned above, a metal oxide material expressed by the general formula A₁₋ₓBₓMn_{z}O_{w} or the general formula A₁₋ₓ(B_{1-y}C_{y})ₓMn_{z}O_{w}, for example, may be used as the material for the thermal resistor substances 34. Also, the thermal resistor substances 34 are grown as single crystals by lattice-matching the conductive film 31 and the thermal resistor substances 34.

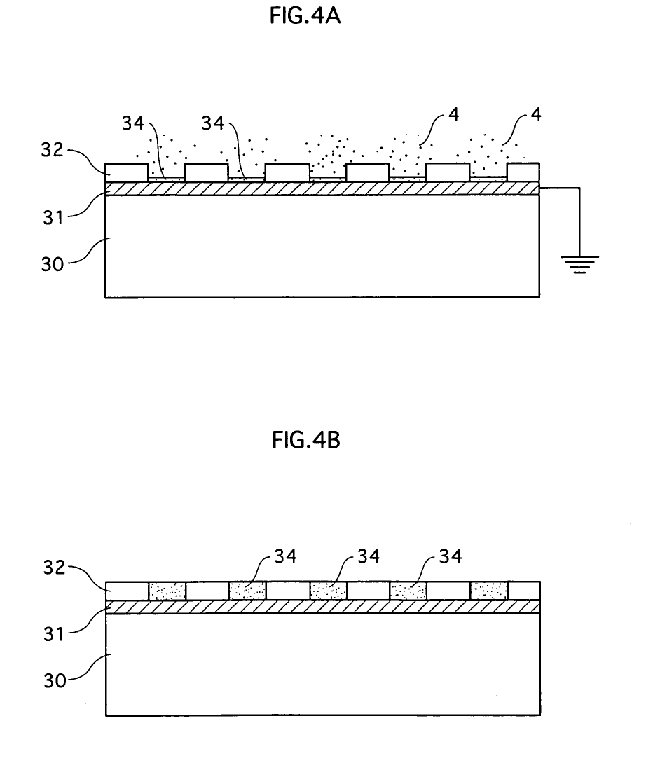

For example, a gaseous material may be ion clusterized and supplied in order to selectively grow the thermal resistor substances 34. FIGS. 4A and 4B are cross-sectional views showing a manufacturing method for selectively growing the thermal resistor substances 34 by supplying an ion-clusterized gaseous material.

As shown in FIG. 4A, the silicon substrate 30 is placed and held on a heating apparatus in a reaction chamber (not depicted), and the conductive film 31 is electrically grounded. While maintaining this state, a gaseous material 4 is supplied.

Similarly to as mentioned above, the gaseous material 4 is a gas used in metal organic chemical vapor deposition, which is passed through a corona discharge path to be ionized and organized into charged ion clusters.

In the present embodiment, the ion-clusterized gaseous material 4 collects in the apertures 33 since an electric field is generated such that an electrostatic potential gradient occurs with respect to the silicon substrate 30 that electrically grounded the conductive film 31 in the reaction chamber.

Furthermore, given that the silicon substrate 30 is heated to a temperature near a thermal decomposition temperature of the gaseous material 4, the gaseous material 4 thermally decomposes over the conductive film 31, and the thermal resistor substances 34 are grown in the apertures 33. FIG. 4A shows thermal decomposition of the gaseous material 4 in the apertures 33, and growth of the thermal resistor substances 34. Here, the process in which the gaseous material 4 condenses at lower portions of the apertures 33 where the conductive film 31 is exposed includes self-organization (i.e., a case of self-aligningly condensing due to chemical affinity between particles of the same type or clusters).

Also, single crystal thermal resistor substances 34 are grown epitaxially on the conductive film 31 since a crystal lattice constant of the conductive film 31 and a crystal lattice constant of the thermal resistor substances 34 are substantially equal. Furthermore, the gaseous material 4 does not condense other than in the apertures 33 and the vicinities thereof, and therefore does not thermally decompose except for these portions. As shown in FIG. 4B, single crystal thermal resistor substances 34 are thus grown only in the apertures 33 where the conductive film 31 is exposed.

Here, it is preferable if the single crystal thermal resistor substances 34 are grown such that their specified crystal orientation is aligned perpendicular with respect to the surface of the conductive film 31.

Also, a silicon oxide film is used as the thin film 32 in the present embodiment. Due to being an insulating material, the silicon dioxide film can be used, as is, as an interlayer insulation film.

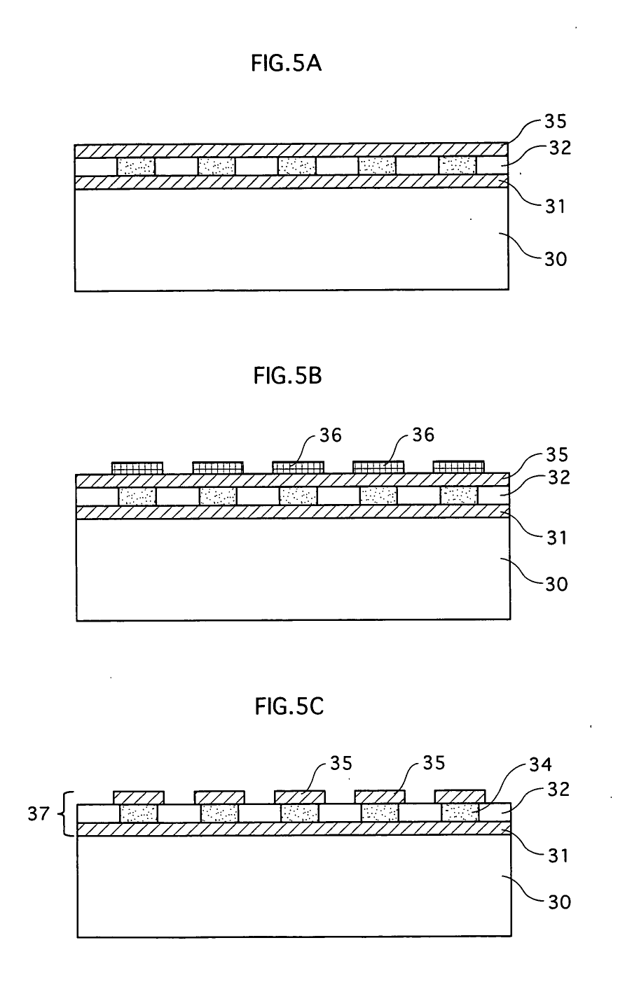

FIGS. 5A to 5C are cross-sectional views showing the manufacturing method of the thermal resistance elements of the infrared imaging device pertaining to the present embodiment, continuing from FIGS. 3A to 3C. As shown in FIG. 5A, a conductive film 35 is formed on surfaces of the thin film 32 and the thermal resistor substances 34. As is clear from the figure, the thermal resistor substances 34 have been grown in the previous process so as to be substantially equal in height with the thin film 32.

Next, as shown in FIG. 5B, a resist mask 36 is formed so as to cover upper portions of the thermal resistor substances 34. This resist mask 36 is formed to match a shape of electrodes included in the thermal resistance elements including the thermal resistor substances 34, not electrodes of the conductive film 31.

FIG. 5C shows a state of the infrared imaging element after portions of the conductive film 35 that are not covered by the resist mask 36 have been removed, and the resist mask 36 has been removed as well. Thereafter, the infrared imaging element is completed by connecting each of the conductive films 31 and 35 to peripheral semiconductor circuitry.

This process enables single crystal thermal resistor substances 34 to be obtained. It is therefore possible to significantly improve the response of the thermal resistance elements since there are no crystal grain boundaries which cause a reduction in sensitivity.

Also, forming the thermal resistor substances 34 selectively on the exposed conductive film 31 at the bottom of the apertures results in few damaged regions 30, and enables the high sensitivity inherent in the material to be exerted. As a result, read properties and write properties of data for each pixel are significantly improved.

### (3) Embodiment 3

Although an infrared imaging device pertaining to the present embodiment has a structure that is generally the same as the infrared imaging device pertaining to embodiment 2, the thermal resistor substances in the present embodiment are formed in a different way from embodiment 2.

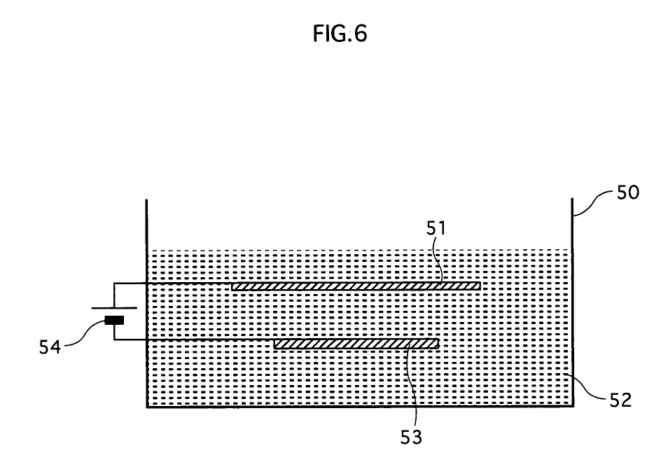

FIG. 6 corresponds to FIG. 4 of embodiment 2, and schematically shows a manufacturing method for selectively growing thermal resistor substances by providing material particles using electrophoresis.

In FIG. 6, a liquid-phase processing tank 50 is filled with a colloid solution 52 in which colloid particles composed of a thermal resistor substance are suspended, and a silicon substrate 51, which has been processed up to and including the state in FIG. 3C, is immersed in the colloid solution 52. A flat-plate electrode 53 is also immersed in the colloid solution 52, and disposed opposing the silicon substrate 51. Also, an electrode 54 is used to apply a voltage to both the silicon substrate 51 and the electrode 53 to generate a difference in potential therebetween.

An acidity of the colloid solution 52 is adjusted such that the thermal resistor substance particles monodisperse. Also, these particles diffused in the colloid solution 52 have been prebaked to result in crystal phase which develops ferroelectricity. The particles therefore are a single crystal, and their dielectric constant has strong anisotropy.

As mentioned above, an electric field is generated between the silicon substrate 51 and the electrode 53, and the particles are selectively attracted to exposed areas of the conductive film over the silicon substrate 51 due to the interaction between this electric field and the dipole moment of the particles. As a result, the thermal resistor substances are crystal-oriented so as to maximize the sensitivity of the thermal resistance elements, and are selectively oriented on the conductive film. This enables thermal resistor substances to be grown on the conductive film.

In the present embodiment as well, the infrared imaging element can be obtained by then performing processes such as those shown in the above-mentioned FIGS. 5A to 5C, in the same way as the above embodiments. It is also possible to maximize the sensitivity of the thermal resistance elements since thermal resistor substances manufactured in this way are a single crystal or aggregations of single crystal particles with aligned crystal orientations. Consequently, the temperature resolution of these thermal resistance elements is significantly improved over that of conventional thermal resistance elements composed of multicrystals.

Also, steps for manufacturing the thermal resistance elements 10 can be eliminated if the thermal resistor substance particles all have the same shape. This enables a reduction in damaged regions and the increased sensitivity, thereby significantly improving the temperature resolution of each pixel.

In particular, the disposition selectivity of the particles and the homogeneity of the electrical properties of the thermal resistance elements can be significantly improved if the standard deviation that expresses the degree of variance of the diameters of the particles is made less than or equal to an average value of the particle diameters.

Also, it is possible to increase the translational motion energy of the particles over the surface of the silicon substrate 51 if the substrate is mechanically oscillated using ultrasound or the like during electrophoresing of the particles. This further increases selectivity. It is also possible to obtain the same effect by irradiating the particles with an energy beam such as a light beam, electron beam, or the like to increase the translational motion energy.

### INDUSTRIAL APPLICABILITY

The present invention can be used as an infrared detection device and a manufacturing method for the same, and is particularly industrially applicable as technology for improving a thermal sensitivity of an infrared detection device.

1-24. (canceled)

25. A manufacturing method for an infrared detection device including a thermal resistance element in which a thermal resistor substance whose resistance changes according to temperature contacts an electrode, the manufacturing method comprising:
an electrode formation step of forming the electrode in a predetermined shape on a substrate; and
a growth step of selectively growing the thermal resistor substance on only the electrode.

26. A manufacturing method for an infrared detection device including a thermal resistance element in which a thermal resistor substance whose resistance changes according to temperature contacts an electrode, the manufacturing method comprising:
an electrode formation step of forming the electrode on a semiconductor substrate;
a thin film formation step of forming a thin film on the electrode;
a thin film removal step of removing a portion of the thin film to expose the electrode;
a growth step of growing the thermal resistor substance on the exposed electrode; and
a step of forming a conductive film on the thin film and on the thermal resistor substance.

27. The manufacturing method of claim 25, wherein
the growth step selectively grows the thermal resistor substance on only the electrode by a vapor growth method.

28. The manufacturing method of claim 26, wherein
the growth step selectively grows the thermal resistor substance on only the electrode by a vapor growth method.

29. The manufacturing method of claim 27, wherein
the vapor growth method is a metal-organic chemical vapor deposition method.

30. The manufacturing method of claim 28, wherein
the vapor growth method is a metal-organic chemical vapor deposition method.

31. The manufacturing method of claim 27, wherein the growth step includes:
a vaporization step of vaporizing a composition material of the thermal resistor substance into a gaseous material;
an ion clusterization step of ion clusterizing the gaseous material;
a collection step of collecting the ion clusterized gaseous material on the electrode by giving the electrode a predetermined electric potential to generate an electric field; and
a condensation step of causing the ion clusterized gaseous material to condense on the electrode by heating the electrode to a predetermined temperature, to grow the thermal resistor substance.

32. The manufacturing method of claim 28, wherein the growth step includes:
a vaporization step of vaporizing a composition material of the thermal resistor substance into a gaseous material;
an ion clusterization step of ion clusterizing the gaseous material;
a collection step of collecting the ion clusterized gaseous material on the electrode by giving the electrode a predetermined electric potential to generate an electric field; and
a condensation step of causing the ion clusterized gaseous material to condense on the electrode by heating the electrode to a predetermined temperature, to grow the thermal resistor substance.

33. The manufacturing method of claim 25, wherein
the growth step selectively grows the thermal resistor substance on only the electrode by a liquid-phase growth method.

34. The manufacturing method of claim 26, wherein
the growth step selectively grows the thermal resistor substance on only the electrode by a liquid-phase growth method.

35. The manufacturing method of claim 33, wherein
the liquid-phase growth method is an electrophoresis method.

36. The manufacturing method of claim 34, wherein
the liquid-phase growth method is an electrophoresis method.

37. The manufacturing method of claim 33, wherein the growth step includes:
a colloidization step of colloidizing a composition material of the thermal resistor substance into colloid particles;
a suspension generation step of generating a suspension including the colloid particles;
an electric field generation step of, with the semiconductor substrate being immersed in the suspension, applying a predetermined voltage to the electrode to generate an electric field; and
an aggregation step of causing the colloid particles to aggregate on the electrode by an action of the electric field, to grow the thermal resistor substance.

38. The manufacturing method of claim 34, wherein the growth step includes:
a colloidization step of colloidizing a composition material of the thermal resistor substance into colloid particles;
a suspension generation step of generating a suspension including the colloid particles;
an electric field generation step of, with the semiconductor substrate being immersed in the suspension, applying a predetermined voltage to the electrode to generate an electric field; and
an aggregation step of causing the colloid particles to aggregate on the electrode by an action of the electric field, to grow the thermal resistor substance.

39. The manufacturing method of claim 25, wherein
a crystal lattice constant of the electrode, along an interface with the thermal resistor substance, is substantially equal to a crystal lattice constant of the thermal resistor substance.

40. The manufacturing method of claim 26, wherein
a crystal lattice constant of the electrode, along an interface with the thermal resistor substance, is substantially equal to a crystal lattice constant of the thermal resistor substance.

41. The manufacturing method of claim 25, wherein
a material of the thermal resistor substance is a strongly correlated electron material expressed by a general formula PrₓCa₁₋ₓMnO₃, to which a metal oxide, having a perovskite structure and including an alkaline-earth metal or a rare-earth metal, has been added.

42. The manufacturing method of claim 26, wherein
a material of the thermal resistor substance is a strongly correlated electron material expressed by a general formula PrₓCa₁₋ₓMnO₃, to which a metal oxide, having a perovskite structure and including an alkaline-earth metal or a rare-earth metal, has been added.

43. The manufacturing method of claim 26, wherein
the thin film is an insulation film.

44. The manufacturing method of claim 25, wherein
the thermal resistor substance is a single crystal.

45. The manufacturing method of claim 26, wherein
the thermal resistor substance is a single crystal.

46. An infrared detection device including a thermal resistance element in which a thermal resistor substance whose resistance changes according to temperature contacts an electrode, wherein
the thermal resistor substance has been selectively formed on only the electrode that was formed on a substrate.

47. The infrared detection device of claim 46, wherein
a crystal lattice constant of the electrode, along an interface with the thermal resistor substance, is substantially equal to a crystal lattice constant of the thermal resistor substance.

48. The infrared detection device of claim 46, wherein
a material of the thermal resistor substance is a strongly correlated electron material expressed by a general formula PrₓCa₁₋ₓMnO₃, to which a metal oxide, having a perovskite structure and including an alkaline-earth metal or a rare-earth metal, has been added.

49. The infrared detection device of claim 46, wherein
the thermal resistor substance is a single crystal.
